(19) United States
(12) Patent Application Publication
(10) Pub. No.: US 2018/0275310 A1
(43) Pub. Date: Sep. 27, 2018

(54) Optoelectronic Sensor and Method for Detecting Objects

(71) Applicant: SICK AG, Waldkirch (DE)

(72) Inventors: Ingolf HÖRSCH, Waldkirch (DE); Kai WASLOWSKI, Waldkirch (DE); Gerhard MERETTIG, Waldkirch (DE); Matthias GÖTZ, Waldkirch (DE)

(21) Appl. No.: 15/933,750

(22) Filed: Mar. 23, 2018

(30) Foreign Application Priority Data
Mar. 24, 2017 (DE) 102017106380.3

(51) Int. Cl. G01V 8/14; G01C 3/08; G01S 17/02; G01S 17/48; H03K 17/968; G01S 7/48; G01S 7/484; G01S 7/486; G01B 11/02

(52) U.S. Cl. CPC G01V 8/14; G01C 3/08; G01S 17/026; G01S 17/48; G01B 11/026; G01S 7/4808; G01S 7/484; G01S 7/4861; H03K 17/968

(57) ABSTRACT

An optoelectronic sensor (10) is provided that has a light transmitter (12) for transmitting light (16) into a monitored zone (18); a light receiver (26) having a first plurality of light reception elements (28) for receiving the light (22) reflected or remitted at objects (20) in the monitored zone (20); and a switching signal unit (32) for generating a switching signal from the reception signals of the light reception elements (28). In this respect, a light distribution measurement unit (36) is provided for generating a light distribution signal spatially resolved over the light reception elements (28) from the reception signals of the light reception elements (28) in parallel with the generation of the switching signal.

The invention relates to an optoelectronic sensor, with the optoelectronic sensor comprising: a light transmitter for transmitting light into a monitored zone; a light receiver having a first plurality of light reception elements for receiving the light reflected or remitted at objects in the monitored zone; a switching signal unit for generating a switching signal from the reception signals of the light reception elements. The invention further relates to a method for detecting objects in a monitored, in which light is transmitted into the monitored zone and is received again after reflection or remission at an object by a plurality of light reception elements, with a switching signal being generated from the reception signals of the light reception elements.

A number of optoelectronic sensors have a reception channel having an imaging optics or a reception lens and having a row-shaped or matrix-like receiver of a plurality of reception elements or pixels. On the one hand, a spatially resolved signal can thus be generated to characterize the reception light spot or to acquire calibration or measurement information from the light spot position. On the other hand, there is the possibility of connecting pixels to one another to form a group or a few groups, for instance via a parameterization, and to process their common signal, in particular a sum signal, to an object detection signal.

A specific class within these sensors utilizes the optical measurement principle of triangulation. The light spot position on a receiver element here represents a measure for the object distance. In this respect, a distinction can again be made between sensors for an actual distance measurement that are an example for an evaluation of the spatially resolved signal and reflection sensors having background suppression or background suppressing light sensors (BGS sensors) that form an example for a group-wise processing to an object detection signal.

A background suppressing light sensor recognizes the presence of objects and typically outputs this in the form of a binary switching signal. In this respect, the triangulation principle is utilized to generate two reception signals using a light receiver spatially resolving at least into a near zone and a far zone. Their difference is evaluated with a switching threshold close to or equal to zero in order thus to restrict the object detection to a specific distance zone and to suppress reception signals from objects outside this distance zone as a background signal. A background suppressing light sensor is disclosed, for example, in DE 197 21 105 C2, wherein here switches are provided to associate the individual elements of a spatially resolving light receiver in a variable manner to the near zone or far zone.

In a simple implementation, a differential diode is sufficient as a light receiver. The switching point is fixed by the border between its near element and far element. The switching point can be set by a mechanical adjustment of the position of the receiver lens or of the reception component. If the switching point is to be changed electronically, a reception element having a plurality of small light reception elements or pixels is used, that is a receiver array, and the mechanical adjustment is replaced with the formation of a respective group of light reception elements for the near zone and the far zone.

The reception signals are not processed as raw signals. They are rather treated in a complex analog and digital manner for a sufficient robustness in the industrial environment. This effort can only be economically represented for a limited number of reception signals and in no way for every single pixel. The individual signals of the light reception elements are therefore first combined to form some few reception channels that then work with the required reliability and a very high temporal resolution. It is a disadvantage of this concept that the distance from the object does not also drop as a measurement parameter in this kind of measurement. It is only known whether the object is disposed before or after the set switching point.

A triangulation sensor for a distance measurement in contrast works with a pixel-based signal processing. Every individual photodiode of the receiver array separately integrates the reception signal. All the pixels are sequentially read and digitized after the signal recording. As already stated above, it is not possible to provide a signal treatment for so many individual signals that corresponds to what can conventionally be implemented in a background suppressing light sensor. A distance-measuring triangulation sensor has a reduced DC light resistance and a reduced dynamic range since each pixel always integrates the complete reception light from useful light and interference light. In addition, the interference light suppression is poor because a temporal interference light filtering is not possible with a high sampling rate at the pixel. Finally, a very high response time also results because the reception signals of a very large number of pixels have to be read out, digitized and evaluated for every measurement. It is therefore possible to say that the high temporal measurement resolution at a high switching frequency and good interference suppression of a background-suppressing light sensor is replaced with a high geometrical resolution.

It is also known in the prior art to detect the individual reception signals of all the pixels in a background suppressing light sensor, that is so-to-say to scan the receiver array. This thus replaces and blocks the switching signal generation and is therefore only possible outside the actual operation, for example in a diagnostic mode. Such conventional sensors can accordingly only alternatively provide a presence of objects at a full switching frequency or can scan the receiver array because the two different observations of the reception signals cancel one another.

It is therefore the object of the invention to further improve a sensor having a spatially resolved light receiver and a generation of a switching signal.

This object is satisfied by an optoelectronic sensor and by a method for detecting objects in a monitored zone in accordance with the respective independent claim. The sensor comprises a light transmitter and a light receiver, wherein the light receiver has a plurality of light reception elements or pixels, preferably in a row, or also in different arrangements such as a multiple row or a matrix. A switching signal is generated for the reception signals of the light reception elements when an object is detected. Alternatively, a plurality of switching signals are generated from a plurality of pixel groups of the light receiver.

The invention now starts from the basic idea of combining the functionality of a switching signal generation with a detection of the light distribution. For this purpose, a light distribution measurement unit generates a spatially resolved light distribution signal from the reception signals of at least some, preferably all, of the light reception elements. This is ultimately the function of the intensity or of the reception level in dependence on the location on the light receiver, in particular a reception level per light reception element or pixel. The position of the light spot, its width, an average intensity, and similar measurement information can inter alia be determined from this in further evaluation steps. In this respect, the evaluations for the switching signal and the light distribution signal run in parallel next to one another or simultaneously. A current switching signal is in particular constantly available at a non-reduced rate or speed even though the light distribution signal is also generated in parallel.

The invention has the advantage that the advantages of a fast, switching sensor are combined together with the robust determination of a light distribution in one unit. In other words, an object or edge detection at a non-reduced switching frequency and a measurement of the light distribution that is comparatively slow as a rule take place simultaneously. The information on the energy distribution on the light receiver is acquired synchronously with a switching signal provided in a robust and fast manner for purposes of measurement, setting and diagnosis in comparison with an only switching sensor. Only a little additional effort is required in this respect. The same optical and signal-generating components are used; only the evaluation function is expanded.

The light transmitter and light receiver preferably form a triangulation arrangement, that is they are arranged and aligned with respect to one another in accordance with the triangulation principle such that the transmitted light reflected or remitted in the monitored zone and received again on the light receiver has a deviation dependent on the distance of the respective sensed object. In this respect, the switching signal unit preferably generates a switching signal in accordance with the principle of a background suppressing sensor. This means that switching takes place in dependence on the presence of an object, but restricted to a specific distance zone by suppression of reception signals of objects outside this distance zone as a background signal. The principle of background suppression or of a background suppressing sensor was explained in the introduction. The function of a switching signal generation with background suppression is hereby expanded by a triangulation-based distance measurement (displacement) or, in other words, a reflection light sensor with background suppression and a distance or displacement measurement sensor are realized in the same sensor.

The light distribution measurement unit as a distance measurement unit is preferably configured to determine a distance from the light distribution signal. In this respect, the deviation of the light spot from the light distribution signal is detected and a precise measurement value for the distance of the sensed object is determined therefrom in accordance with the triangulation principle. The distance can be determined from a focal point, median, or a comparable parameter for the position determination of the reception light spot via a triangulation-based conversion between the position on the light receiver and the object distance. The association with the light distribution measurement unit is first purely functional; a spatially or logically directly associated real implementation is only advantageous, but not compulsory. It is ultimately inconsequential for the sensor at which point this evaluation specifically takes place.

The switching signal unit is preferably configured to determine a separation web between light reception elements for near objects and light reception elements for far objects using the light distribution signal, in particular using a distance determined therefrom. In this respect, near objects are those on whose detection a switching should take place while far objects only represent background to be suppressed. Since the sensor can itself measure distances, it is very simple to teach the separation web by presentation of an object at the desired distance. In addition, the sensor can respectively measure a distance from the background and the object and can place the separation web therebetween. This is even conceivable for tracking in operation.

The switching signal unit preferably has at least a near zone signal composed of combined reception signals of light reception elements that receive light from objects at a near distance and a far zone signal composed of combined reception signals of light reception elements supplied to it that receive light from objects at a far distance, with the switching signal unit being configured for the generation of the switching signal to evaluate the difference between the near zone signal and the far zone signal with a threshold. This is a specific method for switching signal generation in accordance with the principle of a background suppressing light sensor. The terms near and far are only to be understood as relative; a specific absolute distance can be near in one application and far in another application. Since the reception light spot migrates over the light receiver in accordance with the triangulation principle with a changed distance, the transition between the near zone and the far zone in the monitored zone corresponds to a position on the light receiver where the transition is also called a separation web. As already mentioned in the introduction, the separation web can be mechanically or electronically adjustable. In this respect, the separation web can be disposed on the border between two physical pixels; however, there are also possibilities of defining it with sub-pixel precision.

The sensor preferably has a second plurality of processing channels for reception signals of the light reception elements, with the second plurality being smaller than the first plurality. A respective plurality of light reception elements thus share an analog and a digital signal evaluation to limit costs and space requirements. A complex and/or expensive signal treatment would in particular only be able to be provided with difficulty for each pixel in an economic manner. The second plurality is preferably even considerably smaller than the first plurality. An order of magnitude of a hundred or even considerably more light reception elements then face only a few, at most ten, processing channels. Preferred embodiments manage with three or four processing channels.

The near zone signal preferably runs through at least one near processing channel and the far region signal through at least one far processing channel. Two processing channels are thus specifically associated with the near and far zones for a background suppression. The distribution of near and far zone signals over a respective plurality of processing channels is, however, conceivable and can produce a more favorable modulation and an improved noise behavior on an A/D conversion. This is, however, not distinguished linguistically in the following, where only one near and one far processing channel is respectively named as representative.

The reception signal of a light reception element at the separation web between light reception elements for the near zone signal and light reception elements for the far zone signal preferably runs through a sub-processing channel and the switching signal unit adds the signal of the sub-processing channel for a sub-pixel resolution proportionally to the near zone signal and to the far zone signal. This is a possibility of achieving the sub-pixel resolution already addressed above. The separation web is no longer dependent on physical borders between light reception elements. The proportion is for example, a factor that is fixed on the setting of the switching interval or of the position of the separation web, for instance in a teaching step. A corresponding proportion of the sub-processing channel is then added to the near zone or to the far zone respectively. A pixel at the border between the near and far zones is thus effectively divided at a desired separation web position of sub-pixel precision.

The reception signals of at least one light reception element preferably run through a measurement processing channel, with the light distribution measurement unit generating the light distribution signal from the signal of the measurement processing channel. There is thus a separate processing channel for the distance measurement.

The at least one light reception element that runs through the measurement processing channel preferably changes cyclically in order thus to gradually build up the light distribution signal. The desired spatial resolution is achieved in this manner by a kind of scanning of the light reception element. The change preferably takes place within the framework of measurement repetitions in which, for example, a transmitted pulse is transmitted at a measurement repetition frequency. Such fast measurement repetitions are anyway provided in a number of embodiments for a high switching frequency. The respective result, that is the signal of the measurement processing channel, can be stored in a buffer or register in which a current light distribution signal is formed in the course of the cycle. The respective reception signal of only one light reception element is preferably supplied to the measurement processing channel because the highest spatial resolution results with this and the cycle runs through all the light reception elements. It is possible to deviate from both conditions. For example, j>1 light reception elements are simultaneously supplied to the measurement processing channel, with a corresponding loss of spatial resolution, or despite j>1, a further displacement only takes place by a respective 1<k<j light reception elements in a kind of nested processing on the change. The cycle can omit some of the light reception elements so that the measurement is effectively restricted to a certain part range of the possible distances.

Even more preferably, the measurement processing channel is also connected to the switching signal unit. The at least one light reception element whose reception signal runs through the measurement processing channel can then also be considered there as if it had also run through the distance processing channel, near processing channel or sub-processing channel. The switching signal generation can thus take place such as if there were no measurement processing channel since the switching signal unit has the reception signals of all the light reception elements still available to it in the correct association. From the point of view of the switching signal unit, the measurement processing channel works like a dynamically changing sub-channel, i.e. a sub-channel connected to different light reception elements, of the near, far or sub-processing channels.

The processing channels are preferably configured for an analog and/or digital signal treatment of the reception signals, in particular using an amplifier, a filter for DC light portions, an A/D converter, a smoothing filter and/or a frequency filter. A substantially more robust detection is thereby made possible. Since there are only comparatively few processing channels, it is also possible to work with more complex modules without too great an effort. An exemplary signal processing provides an amplification, a filtering of the DC light portion and, after an A/D conversion, further digital filters such as a FIR filter in the analog part. The high speed of the generation of a switching signal is thus associated with a high robustness.

The smoothing filter and/or frequency filter is preferably a FIR filter of at least the second order, that is of the order m≥2. This means that the FIR filter has at least 2+1=3 sampling points and is, in the simplest case for example, an O-S-O (background-signal-background) process. At higher orders, the alternation O-S-O-S-O . . . can be continued. The sampling points in the signal are in particular acquired by repeated transmission of a light pulse and sensing the associated reception signal; the sampling points in the background by intermediate sensing procedures. Two or more filters can also work in parallel with one another and filter the signal in different manners.

The sensor preferably has a multiplex unit for connecting the light reception elements to a respective processing channel. It is thus possible to associate which light reception element belongs to which processing channel. The separation web can thus be set and changed in that light reception elements are connected to a near processing channel, a far processing channel and, optionally, to a sub-processing channel. The multiplex unit is even more preferably programmable to be able to simply change the associations.

The sensor preferably has a switching output for outputting the switching signal and an interface for outputting the light distribution signal and/or a measurement parameter derived therefrom. The switching output can output the binary result of the object or edge detection at a high switching frequency. At the same time, a typically slower transmission of the light distribution signal or of a parameter derived therefrom is possible via the analog or digital interface. In this respect, a current switching signal is also available in parallel with a slower measurement procedure for a light distribution signal, in particular at each measurement repetition.

The light distribution measurement unit is preferably configured to determine a level, a remission value and/or a light spot width from the light distribution signal. Such a preferably continuous evaluation produces measurement parameters that are typically of more interest for the user than the light distribution signal itself that initially only represents an intensity distribution over the light receiver. The sum or the integral of the light distribution signal is a measure for the total level and this is in turn a measure for the object remission in a triangulation arrangement of known or determinable distance. The light spot width will be considerably smaller with a shiny object having a directed reflection so that statements on the brilliance behavior can be derived herefrom. The symmetry of the light distribution contains information on the object contrast.

The light distribution measurement unit is preferably configured to determine a first light distribution signal for the foreground or a second light distribution signal for the background depending on the switching signal. Specifically, reception signals of the light reception elements, in particular those of the measurement processing channel, are only used for the associated light distribution signal depending on the current switching state. Two different buffers or registers for the two light distribution signals can be provided for this purpose. The result is light distribution signals or spatially resolved light distributions separated into a presence of an object or for the foreground and an absence of an object or for the background.

A distinction is particularly preferably again made into an active and inactive light distribution signal for the two light distribution signals. If namely the switching signal changes its state during the determination of the active light distribution, a mixed measurement result of foreground and background results that cannot be sufficiently reliable. Consequently, it is discarded in accordance with this embodiment and the associated inactive light distribution signal from an earlier complete detection is still used for downstream evaluations and outputs. If an active light distribution signal is completely detected, it is also serves as the future inactive light distribution signal.

The sensor preferably has a second, diffuse light source, with the light distribution measurement unit being configured to record a light distribution signal of the background under diffuse lighting to later compensate measurements therewith. In particular shiny objects or surfaces can thus be traced in the background. The light reception elements in which an interfering reflection is also impending from there in operation can be taken into account with a corresponding damping in the evaluation.

The method in accordance with the invention can be further developed in a similar manner and shows similar advantages in so doing. Such advantageous features are described in an exemplary, but not exclusive manner in the subordinate claims dependent on the independent claims.

The invention will be explained in more detail in the following also with respect to further features and advantages by way of example with reference to embodiments and to the enclosed drawing. The Figures of the drawing show in:

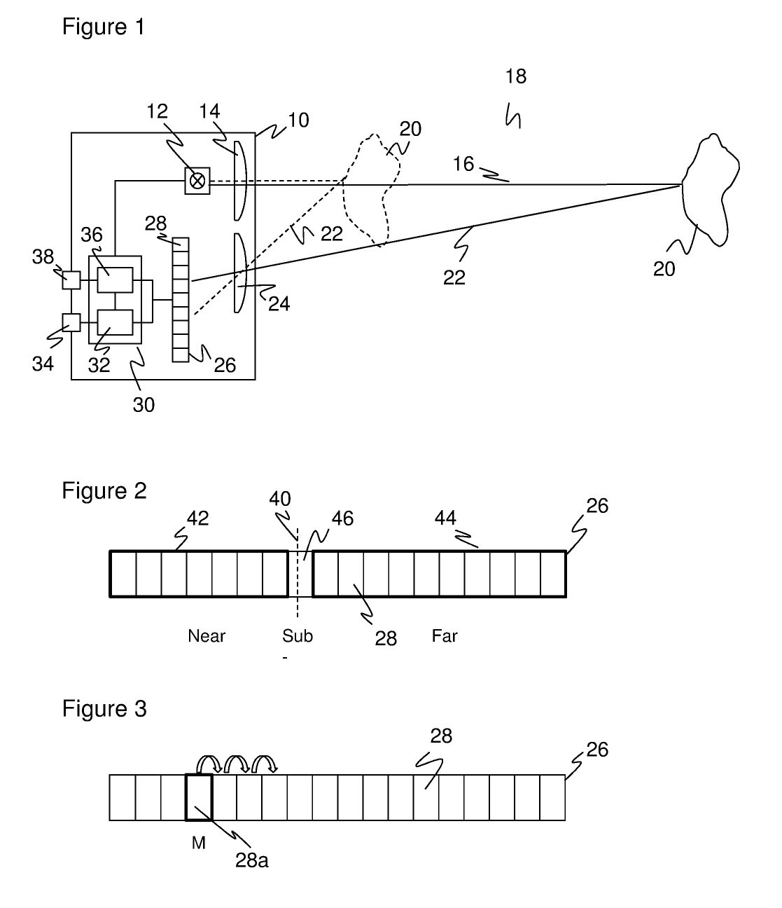

FIG. 1 a schematic sectional representation of an optoelectronic sensor in a triangulation arrangement;

FIG. 2 a schematic view of a pixel-resolved light receiver for explaining the division over processing channels for a background suppression;

FIG. 3 a schematic view of the pixel-resolved light receiver in accordance with FIG. 2, but with an explanation of the association with a measurement processing channel for distance measurement; and

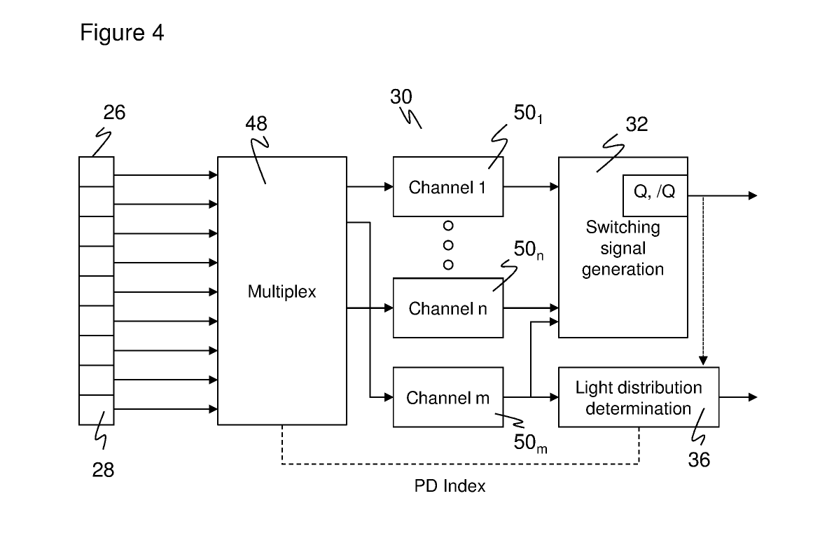

FIG. 4 a block diagram of an evaluation for a parallel switching signal generation and distance determination.

FIG. 1 shows a schematic sectional representation of a sensor 10 in a triangulation arrangement. A typical, but not restrictive, application is the fast object and edge detection with objects moving in from the side, for example at a conveyor belt. The invention will first be explained for a sensor 10 in a triangulation arrangement and only subsequently for other embodiments.

A light transmitter 12 transmits a light beam 16 into a monitored zone 18 via a beam-shaping transmission optics 14. If the light beam 16 is incident on an object 20, a portion of the transmitted light returns to the sensor 10 as a remitted or reflected light beam 22. A reception optics 24 intercepts this remitted light beam 22 and conducts it to a light receiver 26 where the incident light is converted into an electrical reception signal. The light receiver 26 has a plurality of pixels or light reception elements 28, in particular photodiodes. The light reception elements 28 form a row arrangement, but can also be arranged to form a matrix or yet differently in other embodiments.

Due to the triangulation arrangement, in the embodiment in accordance with FIG. 1 the offset between the light transmitter 12 with transmission optics 14 with respect to the light receiver 26 with reception optics 24 and due to the arrangement of the light reception elements 28 along the transverse connection between the light transmitter 12 and the light receiver 26, the remitted light beam 22 of a near object 20 shown by dashed lines is incident onto other light reception elements 28, further above in FIG. 1 than the remitted light beam 22 of a far object 20 shown by solid lines. The position of the reception light spot, also called its deviation, offset, or displacement, that is reflected in which of the light reception elements 28 detects or detect the reception light spot is therefore a measure of the distance of the object 20.

An evaluation unit 30 is connected to the light transmitter 12 or its control and to the light receiver 26 to further evaluate the electrical reception signals of the light reception elements 28. In this respect, an object detection signal is determined in a switching signal unit 32 depending on the presence of an object 20 with background suppression and is output to a switching output 34. In parallel with this, a light distribution signal which detects the distribution of the intensity over the light reception elements 28 is measured in a light distribution measurement unit 36 that can here in particular be configured as a distance measurement unit. The light distribution signal or a measurement parameter derived therefrom is output to an interface 38. Embodiments of the evaluation will be explained in more detail in the following.

FIG. 2 shows a schematic plan view of the light receiver 26. With respect to FIG. 1, the light receiver 26 is rotated out of the plane of the paper and is additionally rotated by 90° clockwise within the plane of the paper. A separation web 40 is defined between a near zone and a far zone for a background suppression. The light reception elements 28 at the left thereof are associated with a near zone 42, the light reception elements at the right thereof with a far zone 44. The light reception element 28 at the transition 46 with the separation web 40 can be treated separately to define the separation web 40 with sub-pixel precision. Alternatively, the separation web 40 can only be placed onto borders between the light reception elements 28.

FIG. 3 shows a further schematic plan view of the light receiver 26. It is the same respective light receiver 26, just in an observation in a different context. The association with specific groups or zones does not relate to the light receiver 26 itself, but rather to the downstream signal processing and evaluation. While FIG. 2 illustrates the background suppression, FIG. 3 serves for the explanation of a distance measurement. A respective light reception element 28a is selected and read out for this purpose. Alternatively, while losing spatial resolution, a larger group of j>1 light reception elements can also be selected. The selection is displaced with every measurement repetition or every signal reading, as indicated by arrows. The light distribution signal or distance determination signal of the spatially resolved intensity of all the successively selected light reception elements 28a is thus gradually created. Such a cycle preferably comprises all the light reception elements 28; however, a partial selection and thus an electronic distance zone selection is also conceivable. A kind of scanning of the light receiver 26 that is comparatively slow is thus required for a detection of a light distribution signal.

The switching signal generation in accordance with FIG. 2 in contrast delivers a current switching signal with each reading step.

FIG. 4 shows a block diagram of an embodiment of the evaluation unit 30. The evaluation unit has a multiplex unit 48 and a plurality of processing channels 50₁ . . . 50ₙ, 50ₘ in addition to the already mentioned switching signal unit 32 and light distribution measurement unit 36. The multiplex unit 48 is connected at the input side to the light reception elements 28 and at the output side to the processing channels 50₁ . . . 50ₙ, 50ₘ. The output signals from n of the processing channels 50₁ . . . 50ₙ are supplied to the switching signal unit 32, to at least one further processing channel 50ₘ of the light distribution measurement unit 36, and preferably additionally to the switching signal unit 32.

The multiplex unit 48, that has a matrix of programmable switches, for example, bundles respective groups of light reception elements 28 to one of the processing channels 50₁ . . . 50ₙ, 50ₘ. It is not precluded in this respect that a group only consists of one light reception element 28, and that is in particular even preferably the case for the further processing channel. The flexibility of the multiplex unit 48 serves an adjustability of the separation web with respect to the processing channels 50₁ . . . 50ₙ. With a fixed separation web or a mechanical adjustment, a multiplexing is not absolutely necessary for this purpose.

The processing channels 50₁ . . . 50ₙ, 50ₘ preferably have an analog and/or digital signal treatment, not shown. This inter alia serves to separate the environmental light generated by sunlight and artificial light sources as completely as possible from the useful light. Different frequency portions can be electronically removed in multiple stages for this purpose. For example, the light from LED lamps having electronic switching power packs causes interference signals having frequency portions up to and into the range of several 100 kHz. It is therefore advantageous to digitize the reception signals at a higher sampling rate of, for example, 1 MHz and then to remove these interference frequencies using a digital filter. A specific implementation can provide a filter for removing the low frequency photodiode current (DC loop), a current-to-voltage converter (transimpedance amplifier, TIA), an analog-to-digital converter, and a digital filter such as a FIR filter. Only some of these elements will be present depending on the embodiment.

Each of the processing channels 50₁ . . . 50ₙ, 50ₘ is thus per se able to generate an output signal that is very robust with respect to interference light in accordance with the supplied reception signals of the associated light reception elements. A conventional distance measurement system having an individual analog-to-digital conversion for every single light reception element has to manage without any comparable signal treatment and is less interference-robust.

128 light reception elements 28 and three processing channels 50₁ . . . 50ₙ for the switching signal generation are provided as an illustrative numerical example that is, however, not to be understood as restrictive. A background suppression having an electronically adjustable separation web 40 with sub-pixel precision can thus be presented with very high resolution, a very good robustness with respect to an interference signal and a high switching frequency. Alternatively, a processing channel 50₁ . . . 50ₙ and the possibility of a setting of the separation web 40 with sub-pixel precision is dispensed with. One processing channel 50₁ is then associated with the near zone and one processing channel 50₂ with the far zone. It can also be advantageous to work with more processing channels 50₁ . . . 50ₙ since then the energy of the remitted transmitted light beam is distributed more, which may result in a more favorable modulation or an improved noise behavior of the A/D converter under certain circumstances.

With the aid of the output signals from the processing channels 50₁ . . . 50ₙ, the switching signal unit 32 produces an object detection signal by a suitable arithmetic linking and evaluation and provides it to the switching output 34. For this purpose, for example, the switching signal is defined as Q:=((N−F)>thresh), where N is the sum of the processing channels 50₁ . . . 50ₖ associated with a near zone, F is the sum of the processing channels 50ₖ₊₁ . . . 50ₙ associated with a far zone, and thresh is a settable threshold, typically close to zero, that can have hysteresis. This corresponds to the typical switching signal of a background suppressing sensor based on triangulation.

To be able to fix the separation web with sub-pixel precision or, in other words, to obtain a higher geometrical resolution of the switching point, an additional processing channel 50; is used that is connected to exactly one light reception element 28 at the transition 46 between the near and far zones and that serves the sub-pixel interpolation. The switching state then results from the modified equation Q:=(N+a V−F>thresh). Here, a is a factor between 1 and −1 that is fixed in the setting of the switching point and V designates the output signal of the additional processing channel 50ᵢ.

The at least one further processing channel 50ₘ is variably associated with one of the light reception elements 28 with the aid of the multiplex unit 48. For this purpose, a counter PD Index is, for example, provided that successively runs through the light reception elements 28 in a cycle. The respective change can be linked to a measurement repetition. For this purpose, a single pulse or a packet of light pulses is repeatedly generated, in particular using a pulse generator, a power source, an LED, or a laser diode of the light transmitter 12. PD Index preferably runs step-wise through all the adjacent light reception elements 28. A different order, larger steps while omitting light reception elements 28, an association of a plurality of light reception elements 28 with the further processing channel 50ₘ, and/or a restriction to a part region of the light reception elements 28 is, however, conceivable.

The output signal of the further processing channel 50ₘ is stored in the light distribution measurement unit 36, for instance in a register, and a light distribution signal is thus successively built up. At the same time, the output signal can also be supplied to the switching signal unit 32 and can in this manner be assigned to exactly that one of the processing channels 50₁ . . . 50ₙ, for example by summation, to which the respective light reception element 28 belongs based on its position. The switching signal generation thereby remains completely unaffected by the additional detection by the further processing channel 50ₘ and the light distribution determination or distance determination. In this respect, only the signal from a respective one of the light reception elements 28 has not taken the normal path over a near or far zone channel 50₁ . . . 50ₙ, but rather the special path over the further processing channel 50ₘ.

In this manner, a switching signal of high robustness is generated simultaneously and with a high repetition rate, that is in particular once per measurement repetition or transmitted pulse, said switching signal not losing anything of robustness and switching frequency with respect to a conventional reflection sensor with background suppression, and additionally a complete light distribution signal that can be evaluated for further measurement parameters is simultaneously assembled, albeit at a smaller measurement rate. The position of the light spot and thus the distance from the object 20 can in particular be determined from this digitized light spot distribution on the light receiver 26. In other embodiments, a switching signal is not derived from every transmitted pulse, but rather from a logical link of a plurality of measurement repetitions. The further processing channel 50ₘ evaluates a different light reception element 28 in parallel thereto, preferably on each measurement repetition, although it is possible to deviate therefrom.

In a preferred embodiment, the data for a switch matrix are provided to the multiplex unit 48 via shift registers. A first shift register having a width of two bits per pixel (for near, sub-pixel, far or “off”) fixes the switch matrix for the switching signal generation. A second shift register having a width of 1 bit per pixel determines whether this pixel is connected to the measurement processing channel or is provided in this form by the first shift register. The first shift register preferably only contains one single “1” and otherwise “0”. The first shift register only has to be written once on the adjustment of the switching point; the second shift register is further cycled per measurement repetition in accordance with the counter PD Index.

It is conceivable that the object distance changes during the detection of a light distribution signal. Averaging would then take place over different object distances. In a number of application situations, namely when objects move laterally in and past at a fixed distance in front of a fixed background, only two object distances always occur. Provision can be made for this purpose in an advantageous further development to distinguish two light distribution signals, namely one for the foreground and one for the background, and to maintain two memories or registers in the light distribution measurement unit 36 for this purpose.

The output signal of the further processing channel 50ₘ is then utilized in dependence on the switching state to detect the light distribution signal for the foreground or for the background. If no object is detected, that is Q=0, the light distribution signal for the background is detected; conversely if an object is detected, that is Q=1, the light distribution signal for the foreground is detected. The light representation signal for the background then represents exactly the light distribution for the switching state “off”, that is the view of the background, and the light distribution signal for the foreground represents the light distribution for the switching state “on”, and consequently the view of the object.

It is also conceivable that the switching state varies during the detection of a light distribution signal. The light distribution signal then remains incomplete or it would again be unfavorably averaged. Such a light distribution signal in which a change of the switching output takes place within a defined time window takes place is therefore preferably discarded as inconsistent. In order nevertheless to have at least almost current light distribution signals available, it can be meaningful to double the memories or registers for the light distribution signals again into active and inactive. The respective light distribution signal from the inactive memory is used for further evaluations and outputs. As soon as a new light distribution signal could be determined without changing the switching state, it is transmitted into the inactive memory or the roles of the active and inactive memories are swapped over.

The light distribution measurement unit 36 can also still further evaluate the respective light distribution signal, in particular continuously, and can provide or display evaluation results at the interface 38. This relates, on the one hand, to a distance determination in which the median or another parameter characterizing the position of the reception light spot such as the focal point of the light distribution signal is determined to derive the object distance therefrom by means of triangulation. Other measurement parameters can also be of interest. For instance, the sum or the integral of the light distribution signal is a measure for the object remission, in particular in combination with the distance information. Statements on the shininess of the object surface can be made from the width of the light spot distribution in the light distribution signal, again in particular in combination with the distance information. The symmetry can serves as a measure for the object contrast.

In a preferred further development, the result of the light distribution measurement unit 36 is used to set the switching threshold. For this purpose, in particular the two light distribution signals for foreground and background are used to set the separation web 40 ideally. This applies both to a set-up phase (teach-in) and to a possible tracking in operation.

In a further advantageous embodiment, the object 20 and its environment are illuminated by a second, diffuse light source. The light distribution signal then includes an angle-distributed view of the background. Background objects with high shininess such as reflective metal surfaces or signs that possibly impair an object detection, then generate a high signal and can be taken into account in a following evaluation step or teaching process, for instance by damping or even switching off the respective light reception elements 28.

The invention has previously been explained at a number of passages while having recourse to a background suppressing sensor. It can, however, furthermore also generally be used in different sensors such as laser stripe sensors, light band sensors, or reflection light barriers having a plurality of evaluation zones that are based on the use of a light receiver 26 having a plurality of light reception elements 28, whether in a row arrangement or also in a matrix arrangement. In this respect, a triangulation arrangement can be selected; however, the invention is not restricted thereto.

In such a sensor, the light distribution signal can be used for an evaluation of the present detection situation supplementing a switching signal. For example, a shiny object generates one or more smaller light spots on the light receiver 26, that are recognizable as maxima in the light distribution signal, due to its directed remission characteristics.

As briefly mentioned in the introduction, there are sensors that define one or more active zones on their light receiver 26. Such a sensor is, for example, only roughly mechanically aligned and then taught where the reception light source is located and the respective light reception elements 28 are selected and evaluated together for an object determination. This also works in the same manner for multichannel systems having a plurality of active zones and a plurality of switching or object detection signals. The light distribution signal delivers the necessary information to fix the zones. They can even be tracked in ongoing sensor operation, for example to compensate a thermal drift.

Conversely, to adapt active zones to a light spot that should be measured, there can also be suppression zones. They can in turn be fixed in order, for example, to suppress a transport belt, or can be formed dynamically, for instance by interference light. The light distribution signal permits such zones to be fixed, adapted, and tracked in advance and also in ongoing operation.

A further conceivable evaluation of the light distribution signal relates to a contamination of the front screen that typically terminates a sensor housing in the region of the light passage. Increasing contamination produces more scattered light reflected in the sensor and thus to a more or less homogeneous increase of the signal level of all the light reception elements 28. This so-to-say forms a noise level and the contamination can be recognized thereat and a corresponding warning signal or maintenance signal can be output.

1. An optoelectronic sensor, the optoelectronic sensor comprising:
a light transmitter for transmitting light into a monitored zone;
a light receiver having a first plurality of light reception elements for receiving the light reflected or remitted at objects in the monitored zone;
a switching signal unit for generating a switching signal from the reception signals of the light reception elements; and
a light distribution measurement unit configured to generate a light distribution signal spatially resolved over at least some of the light reception elements from the reception signals of the light reception elements in parallel with the generation of the switching signal.

2. The sensor in accordance with claim 1,
wherein the light transmitter and the light receiver form a triangulation arrangement.

3. The sensor in accordance with claim 2,
wherein the switching signal unit generates a switching signal in accordance with the principle of a background suppressing sensor.

4. The sensor in accordance with claim 2,
wherein the light distribution measurement unit is configured as a distance measurement unit to determine a distance from the light distribution signal.

5. The sensor in accordance with claim 2,
wherein the switching signal unit is configured to fix a separation web between light reception elements for near objects and light reception elements for far objects using the light distribution signal.

6. The sensor in accordance with claim 5, wherein the switching signal unit is configured to fix a separation web between light reception elements for near objects and light reception elements for far objects using a distance determined from the light distribution signal.

7. The sensor in accordance with claim 2,
wherein the switching signal unit has at least a near zone signal composed of combined reception signals of light reception elements that receive light from objects at a near distance and a far zone signal composed of combined reception signals of light reception elements supplied to it that receive light from objects at a far distance, with the switching signal unit being configured for the generation of the switching signal to evaluate the difference between the near zone signal and the far zone signal with a threshold.

8. The sensor in accordance with claim 1,
that has a second plurality of processing channels for reception signals of the light reception elements, with the second plurality being smaller than the first plurality.

9. The sensor in accordance with claim 7,
that has a second plurality of processing channels for reception signals of the light reception elements, with the second plurality being smaller than the first plurality wherein the near zone signal runs through at least one near processing channel and the far zone signal runs through at least one far processing channel.

10. The sensor in accordance with claim 9,
wherein the reception signal of a light reception element at the separation web between light reception elements for the near zone signal and light reception elements for the far zone signal runs through a sub-processing channel and the switching signal unit adds the signal of the sub-processing channel for a sub-pixel resolution proportionally to the near zone signal and to the far zone signal.

11. The sensor in accordance with claim 8,
wherein the reception signals of at least one light reception element run through a measurement processing channel; and wherein the light distribution measurement unit generates the light distribution signal from the signal of the measurement processing channel.

12. The sensor in accordance with claim 11,
wherein the at least one light reception element that runs through the measurement processing channel changes cyclically in order thus to gradually build up the light distribution signal.

13. The sensor in accordance with claim 12,
wherein the signal of the measurement processing channel is also added to a processing channel for the generation of the switching signal.

14. The sensor in accordance with claim 8,
wherein the processing channels are configured for an analog and/or digital signal treatment of the reception signals.

15. The sensor in accordance with claim 8,
wherein the processing channels are configured for an analog and/or digital signal treatment of the reception signals using at least one of an amplifier, a filter for DC light portions, an A/D converter, a smoothing filter and a frequency filter.

16. The sensor in accordance with claim 15,
wherein at least one of the smoothing filter and the frequency filter has an FIR filter of at least the second order.

17. The sensor in accordance with claim 8,
that has a multiplex unit for connecting the light reception elements to a respective processing channel.

18. The sensor in accordance with claim 1,
that has a switching output for outputting the switching signal and an interface for outputting at least one of the light distribution signal and a measurement parameter derived therefrom.

19. The sensor in accordance with claim 18, wherein the measurement parameter derived from the light distribution signal is at least one of a level, a remission value and a light spot width.

20. The sensor in accordance with claim 1,
wherein the light distribution measurement unit is configured to determine a first light distribution signal for the foreground or a second light distribution signal for the background depending on the switching signal.

21. The sensor in accordance with claim 1,
that has a second, diffuse light source, with the light distribution measurement unit being configured to record a light distribution signal of the background under diffuse lighting to later compensate measurements therewith.

22. A method of detecting objects in a monitored zone, in which light is transmitted into the monitored zone and is received again after reflection or remission at an object by a plurality of light reception elements, with a switching signal being generated from the reception signals of the light reception elements, wherein a light distribution signal spatially resolved over the light reception elements is also generated from the reception signals of the light reception elements in parallel with the generation of the switching signal.
